(19) United States
(12) Patent Application Publication
(10) Pub. No.: US 2025/0151471 A1
(43) Pub. Date: May 8, 2025

(54) METHOD OF MANUFACTURING LIGHT EMITTING DEVICE

(71) Applicant: NICHIA CORPORATION, Anan-shi (JP)

(72) Inventors: Yasuhiro MIKI, Tokushima-shi (JP); Hirofumi KAWAGUCHI, Tokushima-shi (JP)

(73) Assignee: NICHIA CORPORATION, Anan-shi (JP)

(21) Appl. No.: 18/904,264

(22) Filed: Oct. 2, 2024

(30) Foreign Application Priority Data
Nov. 8, 2023 (JP) 2023-190816

(51) Int. Cl. H01L 33/38; H01L 33/62

(52) U.S. Cl. CPC H10H 20/831; H10H 20/857; H10H 20/032; H10H 20/0364

(57) ABSTRACT

A method of manufacturing a light emitting device includes: preparing a light emitting element comprising an external terminal having a first portion located on a semiconductor structure side and a second portion disposed on the first portion, wherein an area of the second portion is less than an area of the first portion; preparing a substrate having a wiring part; bonding the light emitting element and the wiring part by bringing the second portion of the external terminal into contact with the wiring part; and subsequent to bonding the light emitting element and the wiring part, forming plating continuously on lateral faces of the first and second portions, wherein a thickness of the second portion is 5 μm at most, and wherein the plating is formed such that the plating formed on the wiring part is in contact with the plating formed on the first portion.

### CROSS-REFERENCE TO RELATED APPLICATIONS

This application is based on and claims priority to Japanese Patent Application No. 2023-190816, filed on Nov. 8, 2023, the entire contents of which are incorporated herein by reference.

### FIELD

The present disclosure relates to a method of manufacturing a light emitting device.

### BACKGROUND

For example, Japanese Patent Publication No. H09-129648 discloses bonding together the metal bumps of a semiconductor element and the wiring of an insulating substrate.

### SUMMARY

An object of certain embodiments of the present invention is to provide a method of manufacturing a light emitting device that can enhance the bonding strength between a light emitting element and a wiring part of a substrate.

A method of manufacturing a light emitting device according to one aspect of the present invention includes: preparing a light emitting element including a semiconductor structure, an electrode electrically connected to the semiconductor structure, and an external terminal electrically connected to the electrode and having a first portion located on the semiconductor structure side and a second portion, less in area than the first portion in a plan view, disposed on the first portion; preparing a substrate having an insulation base and a wiring part disposed on the upper face of the insulation base; bonding the light emitting element and the wiring part by bringing the second portion of the external terminal into contact with the wiring part; and, subsequent to bonding the light emitting element and the wiring part, forming plating on the lateral faces of the first portion and the lateral faces of the second portion continuously, wherein the thickness of the second portion is 5 μm at most, and in forming the plating, the plating is formed such that, in the space between the first portion and the wiring part, the plating formed on the wiring part is in contact with the plating formed on the first portion.

The present invention can provide a method of manufacturing a light emitting device that can enhance the bonding strength between a light emitting element and a wiring part of the substrate.

### BRIEF DESCRIPTION OF THE DRAWINGS

FIG. 1 is a schematic cross-sectional view explaining a step in a method of manufacturing a light emitting device according to an embodiment.

FIG. 2 is a schematic cross-sectional view explaining a step in the method of manufacturing a light emitting device according to the embodiment.

FIG. 3 is a schematic cross-sectional view explaining a step in the method of manufacturing a light emitting device according to the embodiment.

FIG. 4 is a schematic cross-sectional view explaining a step in the method of manufacturing a light emitting device according to the embodiment.

FIG. 5 is a schematic plan view of a light emitting element according to an embodiment.

FIG. 6 is a schematic cross-sectional view taken along line VI-VI in FIG. 5.

### DETAILED DESCRIPTION

Certain embodiments of the present invention will be described below with reference to the accompanying drawings. In the drawings, the same reference numerals are used to denote the same constituents. The drawings are schematic representation of the embodiments. As such, the scale, spacing, or positional relationships of the members might be exaggerated, or a certain portion of a member omitted. As a cross-sectional view, an end view only showing a cut section might be used.

In the explanation below, common reference numerals are used to denote members having essentially the same functions for which redundant explanation might be omitted. Terms indicating specific directions or positions (for example, “on,” “upper,” or “under,” “lower” or other terms related thereto) may occasionally be used. These terms, however, are merely used to clarify the relative directions or positions in a referenced drawing. As long as the relationship between relative directions or positions indicated with the terms such as “upper,” “on,” “lower,” “under,” or the like is the same as those in a referenced drawing, the layout of the elements in other drawings or actual products outside of the present disclosure does not have to be the same as those shown in the referenced drawing.

A method of manufacturing a light emitting device according to an embodiment includes preparing a light emitting element, preparing a substrate, bonding the light emitting element and the wiring part of the substrate, and forming plating. Each process will be explained below.

### Preparing Light Emitting Element

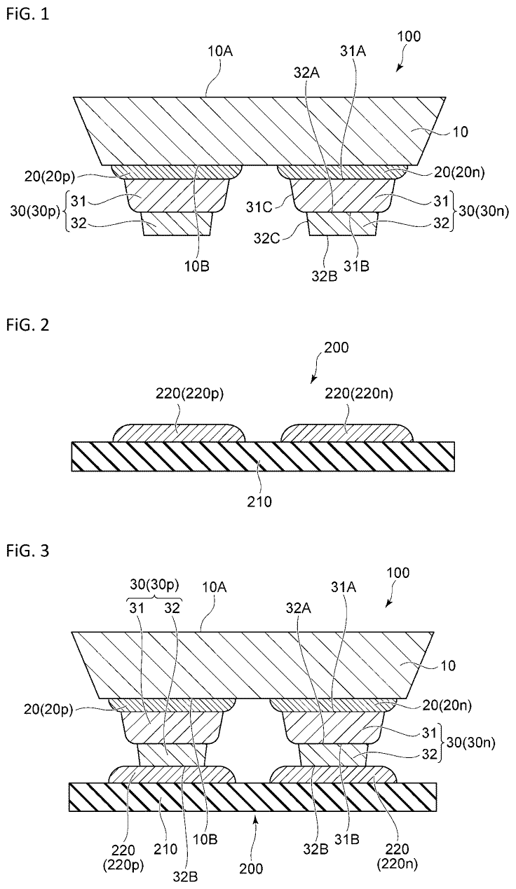

In preparing a light emitting element, a light emitting element 100 shown in FIG. 1 is prepared. The light emitting element 100 has a semiconductor structure 10, an electrode 20 electrically connected to the semiconductor structure 10, and an external terminal 30 electrically connected to the electrode 20.

### Semiconductor Structure 10

A semiconductor structure 10 is made of a nitride semiconductor. In the present specification, the term “nitride semiconductor” includes all compositions obtained by varying the composition ratio x and y within their ranges in the chemical formula InₓAl_{y}Ga_{1-x-y}N (0≤x≤1, 0≤y≤1, x+y≤1). Moreover, those further containing a group V element in addition to nitrogen (N), and those further containing various elements added for controlling various physical properties such as conductivity type are also included in the term “nitride semiconductor.”

The semiconductor structure 10 has a first face 10A and a second face 10B positioned opposite the first face 10A. The semiconductor structure 10, as described later, has an active layer that emits light. The active layer emits light having a peak wavelength of 210 nm to 580 nm, for example. The light emitted by the active layer is extracted from the semiconductor structure 10 primarily through the first face 10A.

### Electrode 20

Multiple electrodes 20 are disposed on the second face 10B of the semiconductor structure 10. The electrodes 20 include an n-side electrode 20n that functions as a cathode electrode and a p-side electrode 20p that functions as an anode electrode. For the electrodes 20, for example, a metal layer, such as titanium (Ti), rhodium (Rh), gold (Au), platinum (Pt), ruthenium (Ru), or aluminum (Al) can be used. The electrodes 20 may be of a single metal layer or a multilayer structure including multiple metal layers.

### External Terminal 30

External terminals 30 include an n-side external terminal 30n that is in contact with the n-side electrode 20n and a p-side external terminal 30p that is in contact with the p-side electrode 20p. Each external terminal 30 has a first portion 31 and a second portion 32. A light emitting element 100 has only to have at least one n-side external terminal 30n and one p-side external terminal 30p. As described later with reference to FIG. 5, in this embodiment, a light emitting element 100 can have four external terminals 30, for example. The thickness of an external terminal 30 can be in a range, for example, from 5 μm to 15 μm. The thickness of an external terminal 30 refers to the maximum value of the distance between the first upper face 31A of the first portion 31 and the second lower face 32B of the second portion 32.

The first portion 31 of the external terminal 30 is located closer to the semiconductor structure 10 than is the second portion 32, and in contact with an electrode 20. The first portion 31 is positioned between the electrode 20 and the second portion 32. The first portion 31 has a first upper face 31A that is in contact with the electrode 20 and a first lower face 31B positioned opposite the first upper face 31A. The first portion 31 further has first lateral faces 31C that connect the first upper face 31A and the first lower face 31B. The thickness of the first portion 31 can be in a range, for example, from 2 μm to 5 μm. The thickness of the first portion 31 is the maximum value of the distance between the first upper face 31A and the first lower face 31B.

In FIG. 1, a second portion 32 is placed under a first portion 31. The second portion 32 is disposed on the first lower face 31B of the first portion 31. The second portion 32 has a second upper face 32A connected to the first lower face 31B of the first portion 31 and a second lower face 32B positioned opposite the second upper face 32A. The second portion 32 further has second lateral faces 32C that connect the second upper face 32A and the second lower face 32B. The thickness of the second portion 32 is in a range, for example, from 3 μm to 10 μm. The thickness of the second portion 32 is the maximum value of the distance between the second upper face 32A and the second lower face 32B.

The first portion 31 and the second portion 32 are made of the same metal, for example. For the first portion 31 and the second portion 32, for example, gold (Au) or copper (Cu) can be used. At least the second face 32B of the second portion 32 is preferably made of gold.

In the cross-sectional view in FIG. 1, the maximum value of the width of a second portion 32 is less than the minimum value of the width of a first portion 31. A second portion 32 is not disposed on a portion of the lower face 31B of a first portion 31.

In the plan view in FIG. 5, the area of a second portion 32 is less than the area of a first portion 31. The area of the second lower face 32B of a second portion 32 is less than the area of the first lower face 31B of a first portion 31. This can maintain the contact area between a first portion 31 and an electrode 20 while lessening the increase in the forward voltage Vf.

Preparing a light emitting element 100 can include, for example, preparing a structure having a semiconductor structure 10 and an electrode 20, and forming on the resultant structure an external terminal 30 by vapor deposition using a resist mask having an opening to expose the electrode 20. In forming an external terminal 30, a first portion 31 is formed under an electrode 20 by vapor deposition by using a first resist mask having an opening that exposes the electrode 20. Subsequent to forming the first portion 31, the first resist mask is removed. Subsequent to removing the first resist mask, a second resist mask having an opening to expose a portion of the first portion 31 is formed, and a second portion 32 is disposed on the first portion 31 by vapor deposition using the second resist mask.

### Preparing Substrate

In preparing a substrate, as shown in FIG. 2, a substrate 200 having an insulation base 210 and wiring parts 220 disposed on the upper face of the insulation base 210 is prepared.

For the insulation base 210, for example, a resin or ceramic material can be used. Multiple wiring parts 220 are disposed on the upper face of the insulation base 210. The wiring parts 220 at least have a first wiring part 220n and a second wiring part 220p. For the wiring parts 220, gold, copper, or the like can be used. The wiring parts 220 each have a single layer structure or a multilayer structure in which different metal layers are stacked. At least the upper face of each wiring part 220 is preferably made of gold.

### Bonding Light Emitting Element and Wiring Part of the Substrate

In bonding the light emitting element 100 and the wiring parts 220 of the substrate 200, as shown in FIG. 3, the second portions 32 of the external terminals 30 are brought into contact with the wiring parts 220 to bond the light emitting element 100 and the wiring parts 220. The n-side external terminal 30n is electronically connected to the first wiring part 220n and the p-side external terminal 30p is electrically connected to the second wiring part 220p.

The second lower faces 32B of the second portions 32 and the upper faces of the wiring parts 220 are bonded, for example, by bringing the second lower faces 32B of the second portions 32 into contact with the upper faces of the wiring parts 220 and applying a load in the direction from the light emitting element 100 to the substrate 200 while heating. For example, the second lower faces 32B of the second portions 32 containing gold and the upper faces of the wiring parts 220 containing gold are bonded by way of gold-to-gold direct bonding. The heating temperature is preferably 100° C. to 300° C., for example. The load applied is preferably 500 N to 1000 N, for example. The load application duration is preferably 1 to 60 seconds, for example.

The thickness of an electrode 20 on which an external terminal 30 is disposed in the light emitting element 100 tends to vary easily, making it difficult to secure an area that is substantially parallel to the upper face of a wiring part 220 to which the external terminal 30 is to be bonded. In a plan view, the thickness of the portion of an electrode 20 on which an external terminal 30 is disposed that is located near the edge of the light emitting element 100 can easily become thinner than the thickness of the portion of the electrode 20 located in the central portion including the center of the light emitting element 100. For this reason, the portions of the electrodes 20 bearing external terminals 30 located near the edges of the light emitting element 100 tend to become relatively thin, making the portions of the lower faces of the external terminals 30 near the edges oblique or curved faces. This reduces the areas of the lower faces of the external terminals 30 that are substantially parallel to the upper faces of the wiring parts 220, which reduces the areas of contact between the external terminals 30 and the wiring parts 220 of the substrate 200 when bonding the external terminals 30 and the wiring parts 220. This can reduce the bonding strength between the external terminals 30 and the wiring parts 220.

According to this embodiment, the first portions 31 of the external terminals are disposed on the electrodes 20, and the second portions 32 are disposed on the portions of the first lower faces 31B of the first portions 31 that are substantially parallel to the upper faces of the wiring parts 220. The area of the second lower face 32B of each second portion 32 that is substantially parallel to the upper face of a wiring part 220 can be increased by disposing the second portion 32 on the face of a first portion 31 that is substantially parallel to the upper face of the wiring part 220 rather than the face near the edge that is oblique to the upper face of the wiring part 220. This can increase the contact area between the second lower face 32B of the second portion 32 and the upper face of the wiring part 220, thereby enhancing the bonding strength between the external terminal 30 and the wiring part 220.

### Forming Plating

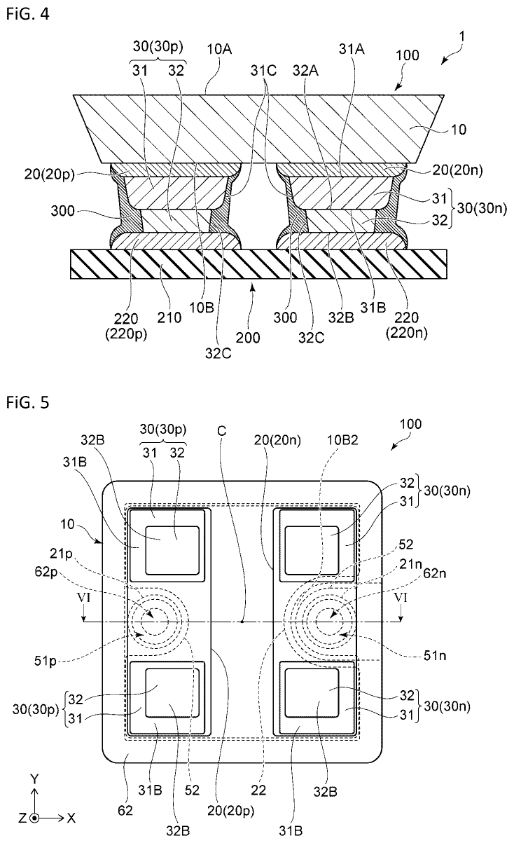

Subsequent to bonding the light emitting element 100 and the wiring parts 220, as shown in FIG. 4, plating 30 is formed. For example, the plating 300 is formed by electroplating or electroless plating. The plating 300 precipitates continuously on the surfaces of the wiring parts 220, the external terminals 30, and the electrodes 20 submerged in a plating solution. The plating 300 precipitate on the lateral faces of the wiring parts 220, the lateral faces of the external terminals 30, and the lateral faces of the electrodes 20. In the case of electroless plating, the plating process is performed by masking the first face 10A and the like on which no plating 300 is allowed to precipitate.

In forming plating 300, the plating 300 is formed continuously on the first lateral faces 31C of the first portions 31 and the second lateral faces 32C of the second portions 32. The plating 300 is formed such that the plating 300 formed on the wiring parts 220 is in contact with the plating 300 formed on the first portions 31 in the space between the first portions 31 and the wiring parts 220. The plating 300 formed in this manner can increase the bonding strength between the external terminals 30 and the wiring parts 220.

According to this embodiment, the second portions 32 having a small thickness, i.e., 5 μm or less, allow the space between the first portions 31 and the wiring parts 220 to be filled easily with the plating 300 deposited not only on the second lateral walls 32C of the second portions 32, but also on the first portions 31 and the wiring parts 220. As a result, the plating 300 on the second lateral walls 32C of the second portions 32 becomes larger in thickness than the plating 300 on the first lateral faces 31C of the first portions 31. The second lateral faces 32C of the second portions 32 being covered by thick plating 300 increases the contact areas between the plating 300 and the wiring parts 220 to thereby enhance the bonding strength between the light emitting element 1 and the wiring parts 220. The difference in thickness between the plating 300 deposited on the second lateral faces 32C of the second portions 32 and the plating 300 deposited on the first lateral faces 31C of the first portions 31 is, for example, in a range from 1 μm to 2 μm.

In the case in which the thickness of a second portion 32 is larger than 5 μm, the plating 300 precipitates primarily on the second lateral faces 32C of the second portions 32, barely resulting in a thickness difference between the plating 300 on the first lateral faces 31C of the first portions 31 (thickness in the direction orthogonal to the first lateral faces 31C) and the plating 300 on the second lateral faces 32C of the second portions 32 (thickness in the direction orthogonal to the second lateral faces 32C).

By following the processes described above, a light emitting device 1 equipped with a substrate 200, a light emitting element 100, and plating 300 is manufactured. For example, a positive potential is supplied to the second wiring part 220p from an external circuit while setting the electric potential of the first wiring part 220n to ground potential. This supplies an electric current from the wiring parts 220 of the substrate 200 to the active layer of the semiconductor structure 10 via the external terminals 30 and the electrodes 20 to allow the active layer to emit light. The number of light emitting elements 100 in a light emitting device 1 is not limited to one, and the light emitting device may have multiple light emitting elements 100 arranged on a single substrate 200.

In a plan view, the area of a second portion 32 is preferably 80% of the area of a first portion 31 at most, more preferably 70% at most. This makes it difficult to position a second portion 32 on any portion of a first portion 31 that is oblique to the upper face of a wiring part 220, and easily increases the area of the portion of the second lower face 32B of the second portion 32 that is substantially parallel to the upper face of the wiring part 220.

A second portion 32 is preferably less in thickness than a first portion 31. This makes it difficult for the peripheral portion of the second lower face 32B of a second portion 32 to become oblique or curved to thereby increase the area of the portion of the second lower face 32B that is substantially parallel to the upper face of a wiring part 220. The difference in thickness between a second portion 32 and a first portion 31 is in a range, for example, from 1 μm to 2 μm.

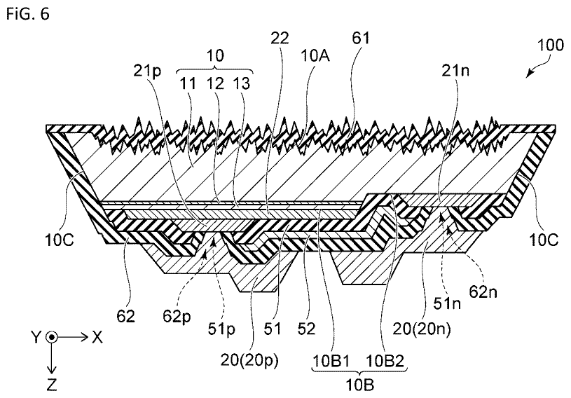

An example of the structure of a light emitting element 100 will be explained in detail with reference to FIG. 5 and FIG. 6.

FIG. 5 is a schematic plan view of the second face 10B side of the semiconductor structure 10. FIG. 6 is a schematic cross-sectional view taken along line VI-VI in FIG. 5. As shown in FIG. 6, there is a height difference between the surfaces of the n-side electrode 20b and the p-side electrode 20p, but the height difference is omitted in FIG. 5 so as not to make the drawing excessively complex.

In FIG. 5 and FIG. 6, directions are indicated using X axis, Y axis, and Z axis. The X, Y, and Z axes are orthogonal to one another. The direction along the X axis is designated as the first direction X, the direction along the Y axis is designated as the second direction Y, and the direction along the Z axis is designated as the third direction Z. In the present specification, a “plan view” means observing the light emitting element 100 from the second face 10B side of the semiconductor structure 10.

As shown in FIG. 6, the semiconductor structure 10 has an n-side semiconductor layer 11, a p-side semiconductor layer 13, and an active layer 12 positioned between the n-side semiconductor layer 11 and the p-side semiconductor layer 13 in the third direction Z. The n-side semiconductor layer 11 has a semiconductor layer containing an n-type impurity. The p-side semiconductor layer 13 has a semiconductor layer containing a p-type impurity. The active layer 12 has, for example, a MQW (multiple quantum well) structure including multiple barrier layers and multiple well layers.

The first face 10A of the semiconductor structure 10 is the face in the n-side semiconductor layer 11 that opposes the active layer 12. The first face 10A can be a rough surface having a number of protrusions. This can increase the efficiency in extracting light through the first face 10A. The plan-view shape of the first face 10A is, for example, a square or rectangle. In the case in which the plan-view shape of the first face 10A is a square, each side is 5 μm to 100 μm in length, for example.

The second face 10B of the semiconductor structure 10 has a first region 10B1 and a second region 10B2. The first region 10B1 is the face of the p-side semiconductor layer 13 that opposes the active layer 12. The second region 10B2 is the face of the n-side semiconductor layer 11 on which the active layer 12 and the p-side semiconductor layer 13 are not disposed. In a plan view, the area of the first region 10B1 is larger than the area of the second region 10B2.

As shown in FIG. 5, the n-side electrode 20n and the p-side electrode 20p are positioned apart in the first direction X. The plan-view shapes of the n-side electrode 20n and the p-side electrode 20p are rectangles having short sides along the first direction X and long sides along the second direction Y. Two n-side external terminals 30n positioned apart in the second direction Y are provided on the n-side electrode 20n. Two p-side external terminals 30p positioned apart in the second direction Y are provided on the p-side electrode 20p. On each of the n-side electrode 20n and the p-side electrode 20p, one external terminal 30, or three or more external terminals 30 may be disposed.

As described above, the thicknesses of the electrodes 20 on which external terminals 30 are disposed at locations near the edges of the light emitting elements 100 can readily become less than the thicknesses in the central location, including the center C, of the light emitting element 100. For this reason, the second portions 32 are preferably localized in the regions of the first portions 31 near the center C of the light emitting element 100 as shown in FIG. 5. Such an arrangement makes a second distance between the center of a second portion 32 and the center C of the light emitting element 100 less than a first distance between the center of a first portion 31 and the center C of the light emitting element 100 in a plan view. This allows the second portions 32 to be disposed on the portions of the first portions 31 that are substantially parallel to the upper faces of the wiring parts 220, thereby increasing the areas in the second lower faces 32B of the second portion 32 that are substantially parallel to the upper faces of the wiring parts 220.

As shown in FIG. 5, the shapes of the first portions 31 and the second portion 32 in the plan view are quadrangles. The first portions 31 each have four first lateral faces 31C and the second portions 32 each have four second lateral faces 32C. The plating 300 covers the four first lateral faces 31C and the four second lateral faces 32C continuously.

As shown in FIG. 4, the portion of the plating 300 formed on the second lateral faces 32C of the second portion 32 of the n-side external terminal 30n that is located on the p-side external terminal 30p side is preferably less in thickness than the plating 300 located on the side not opposing the p-side external terminal. This makes it difficult for a short circuit to occur between the first wiring parts 220n and the second wiring parts 220p via the plating 300. The difference in thickness between the portions of the plating 300 located on the p-side external terminals 30p side and the opposite side is in a range, for example, from 1 μm to 2 μm.

Similarly, the thickness of the portion of the plating 300 formed on the second lateral faces 32C of the second portion 32 of the p-side external terminal 30p that is located on the n-side external terminal 30n side is preferably less than the thickness of the plating 300 on the side not opposing the n-side external terminal 30n. This can make it difficult for a short circuit to occur between the first wiring part 220n and the second wiring part 220p via the plating 300. The difference in thickness between the plating 300 located on the n-side external terminal 30n side and the plating 300 on the opposite side is, for example, 1 μm to 2 μm.

The occurrence of a short circuit between the first wiring part 220n and the second wiring part 220p can be made even less likely by making both the portion of the plating 300 formed on the second lateral faces 32C of the n-side external terminal 30n that is located on the p-side external terminal 30p side and the portion of the plating 300 formed on the second lateral faces 32C of the p-side external terminal 30p that is located on the n-side external terminal 30n side thinner as described above.

The light emitting element 100 can include, in addition to the constituents described above, a first conducting film 21n, a second conducting film 21p, a third conducting film 22, a first light reflecting member 51, a second light reflecting member 52, an insulation film 62, and a protective film 61.

### First Conducting Film 21n and Second Conducting Film 21p

A first conducting film 21n is disposed on the second region 10B2 of the second face 10B and electrically connected to the n-side semiconductor layer 11. A second conducting film 21p is disposed on the first region 10B1 of the second face 10B via a third conducting film 22 and electrically connected to the p-side semiconductor layer 13. For the first conducting film 21n and the second conducting film 21p, for example, a metal layer containing titanium (Ti), rhodium (Rh), gold (Au), platinum (Pt), aluminum (Al), silver (Ag), or ruthenium (Ru) can be used. The first conducting film 21n and the second conducting film 21p may be of a single metal layer or a multilayer structure including multiple metal layers.

### Third Conducting Film 22

A third conducting film 22 is disposed on the first region 10B1 of the second face 10B. The third conducting film 22 has the function of diffusing the current supplied through the p-side external terminal 30p, the p-side electrode 20p, and the second conducting film 21p in an in-plane direction of the p-side semiconductor layer 13. For the material for the third conducting film 22, for example, ITO (indium tin oxide), IZO (indium zinc oxide), ZnO, In₂O₃, or the like can be used.

### First Light Reflecting Member 51

A first light reflecting member 51 covers at least the first region 10B1 side of the second face 10B. The first light reflecting member 51 has a high reflectance for the peak wavelength of the light emitted by the active layer 12. The reflectance of the first light reflecting member 51 for the peak wavelength of the light emitted by the active layer 12 is, for example, 60% or higher, preferably 70% or higher. The light advancing from the active layer 12 to the second region 10B2 side of the second face 10B can be reflected by the first light reflecting member 51 towards the first face 10A. This can increase the efficiency in extracting light from the first face 10A. For the first light reflecting member 51, for example, a dielectric multilayer film comprising multiple dielectric films can be used.

In FIG. 6, the first light reflecting member 51 has a first n-side opening 51n located under the first conducting film 21n and a first p-side opening 51p located under the second conducting film 21p.

### Second Light Reflecting Member 52

A second light reflecting member 52 covers at least the first region 10B1 side of the second face 10B. The second light reflecting member 52 covers the first light reflecting member 51 disposed on the first region 10B1 of the second face 10B. The second light reflecting member 52 has a high reflectance for the peak wavelength of the light emitted by the active layer 12. The reflectance of the second light reflecting member 52 for the peak wavelength of the light emitted by the active layer 12 is, for example, 60% or higher, preferably 70% or higher. The light extraction efficiency can be increased by allowing the second light reflecting member 42 to reflect the light that transmitted through the first light reflecting member 51 towards the first face 10A. The second light reflecting member 52 is, for example, a metal. For the second light reflecting member 52, for example, a metal layer containing Al or Ti can be used. The second light reflecting member 52 may be of a single metal layer or a multilayer structure including multiple metal layers.

### Insulation Film 62

An insulation film 62 is disposed on the second face 10B side and on the lateral faces 10C of the semiconductor structure 10. For the insulation film 62, for example, SiO₂, SiON, SiN, or the like can be used. The insulation film 62 has a second n-side opening 62n and a second p-side opening 62p. As shown in FIG. 5, the second n-side opening 62n is located inward of the first n-side opening 51n of the first light reflecting member 51 in the plan view. The second p-side opening 62p is located inward of the first p-side opening 51p of the first light reflecting member 51 in the plan view.

### Protective Film 61

A protective film 61 covers the first face 10A of the semiconductor structure 10. The transmittance of the protective film 61 for the peak wavelength of the light emitted by the active layer 12 is, for example, 70% or higher, preferably 90% or higher. For the protective film 61, for example, SiO₂, SiON, SiN, or the like can be used.

The n-side electrode 20n is connected to the first conducting film 21n in the first n-side opening 51n and the second n-side opening 62n. The n-side semiconductor layer 11 is electrically connected to the n-side external terminal 30n via the first conducting film 21n and the n-side electrode 20n.

The p-side electrode 20p is connected to the second conducting film 21p at the first p-side opening 51p and the second p-side opening 62p. The p-side semiconductor layer 13 is electrically connected to the p-side external terminal 30p via the third conducting film 22, the second conducting film 21p, and the p-side electrode 20p.

On the second face 10B side of the semiconductor structure 10 of the light emitting element 100, it is difficult to have flat areas at the location in which the n-side semiconductor layer 11 and the n-side electrode 20n are electrically connected and the location in which the p-side semiconductor layer 13 and the p-side electrode 20p are electrically connected. Accordingly, as shown in FIG. 5, it is preferable for the n-side external terminal 30n and the p-side external terminal 30p to not overlap the location in which the n-side semiconductor layer 11 and the n-side electrode 20n are electrically connected (where the first n-side opening 51n and the second n-side opening 62n are located) and the location in which the p-side semiconductor layer 13 and the p-side electrode 20p are electrically connected (where the first-side opening 51n and the second p-side opening 62n are located) in the plan view. This can easily increase the areas of the second lower faces 32B of the external terminals 30 that are substantially parallel to the upper faces of the wiring parts 220.

The embodiments of the present invention can include the methods of manufacturing a light emitting device described below.

In the foregoing, certain embodiments of the present invention have been explained with reference to specific examples. The present invention, however, is not limited to these specific examples. All forms implementable by a person skilled in the art by suitably making design changes based on any of the embodiments of the present invention described above also fall within the scope of the present invention so long as they encompass the subject matter of the present invention. Furthermore, various modifications and alterations within the spirit of the present invention that could have been made by a person skilled in the art also fall within the scope of the present invention.

What is claimed is:

1. A method of manufacturing a light emitting device, the method comprising:
preparing a light emitting element comprising a semiconductor structure, an electrode electrically connected to the semiconductor structure, and an external terminal electrically connected to the electrode and having a first portion located on a semiconductor structure side and a second portion disposed on the first portion, wherein, in a plan view, an area of the second portion is less than an area of the first portion;
preparing a substrate having an insulation base, and a wiring part disposed on an upper face of the insulation base;
bonding the light emitting element and the wiring part by bringing the second portion of the external terminal into contact with the wiring part; and
subsequent to bonding the light emitting element and the wiring part, forming plating continuously on lateral faces of the first portion and lateral faces of the second portion, wherein a thickness of the second portion is 5 μm at most, and wherein the plating is formed such that, in a space between the first portion and the wiring part, the plating formed on the wiring part is in contact with the plating formed on the first portion.

2. The method of manufacturing a light emitting device according to claim 1, wherein, in a plan view, a distance between a center of the second portion and a center of the light emitting element is less than a distance between a center of the first portion and the center of the light emitting element.

3. The method of manufacturing a light emitting device according to claim 2, wherein, in a plan view, the area of the second portion is 80% or less than the area of the first portion.

4. The method of manufacturing a light emitting device according to claim 1, wherein the thickness of the second portion is less than a thickness of the first portion.

5. The method of manufacturing a light emitting device according to claim 2, wherein the thickness of the second portion is less than a thickness of the first portion.

6. The method of manufacturing a light emitting device according to claim 1, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
(i) a thickness of a portion of the plating formed on the second lateral faces of the second portion of the n-side external terminal that is located on a p-side external terminal side is less than a thickness of the plating not on the p-side external terminal side, and/or (ii) a thickness of a portion of the plating formed on the second lateral faces of the second portion of the p-side external terminal that is located on an n-side external terminal side is less than a thickness of the plating not on the n-side external terminal side.

7. The method of manufacturing a light emitting device according to claim 2, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
(i) a thickness of a portion of the plating formed on the second lateral faces of the second portion of the n-side external terminal that is located on a p-side external terminal side is less than a thickness of the plating not on the p-side external terminal side, and/or (ii) a thickness of a portion of the plating formed on the second lateral faces of the second portion of the p-side external terminal that is located on an n-side external terminal side is less than a thickness of the plating not on the n-side external terminal side.

8. The method of manufacturing a light emitting device according to claim 3, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
(i) a thickness of a portion of the plating formed on the second lateral faces of the second portion of the n-side external terminal that is located on a p-side external terminal side is less than a thickness of the plating not on the p-side external terminal side, and/or (ii) a thickness of a portion of the plating formed on the second lateral faces of the second portion of the p-side external terminal that is located on an n-side external terminal side is less than a thickness of the plating not on the n-side external terminal side.

9. The method of manufacturing a light emitting device according to claim 1, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
in a plan view, the n-side external terminal and the p-side external terminal do not overlap a location in which the n-side semiconductor layer and the n-side electrode are electrically connected and a location in which the p-side semiconductor layer and the p-side electrode are electrically connected.

10. The method of manufacturing a light emitting device according to claim 2, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
in a plan view, the n-side external terminal and the p-side external terminal do not overlap a location in which the n-side semiconductor layer and the n-side electrode are electrically connected and a location in which the p-side semiconductor layer and the p-side electrode are electrically connected.

11. The method of manufacturing a light emitting device according to claim 3, wherein:
the semiconductor structure comprises an n-side semiconductor layer, a p-side semiconductor layer, and an active layer positioned between the n-side semiconductor layer and the p-side semiconductor layer;
the electrode comprises an n-side electrode electrically connected to the n-side semiconductor layer, and a p-side electrode electrically connected to the p-side semiconductor layer;
the external terminal comprises an n-side external terminal electrically connected to the n-side electrode, and a p-side external terminal electrically connected to the p-side electrode; and
in a plan view, the n-side external terminal and the p-side external terminal do not overlap a location in which the n-side semiconductor layer and the n-side electrode are electrically connected and a location in which the p-side semiconductor layer and the p-side electrode are electrically connected.

12. The method of manufacturing a light emitting device according to claim 1, wherein a thickness of the first portion is in a range from 2 μm to 5 μm.

13. The method of manufacturing a light emitting device according to claim 2, wherein a thickness of the first portion is in a range from 2 μm to 5 μm.

14. The method of manufacturing a light emitting device according to claim 1, wherein the thickness of the second portion is in a range from 3 μm to 10 μm.

15. The method of manufacturing a light emitting device according to claim 2, wherein the thickness of the second portion is in a range from 3 μm to 10 μm.

16. The method of manufacturing a light emitting device according to claim 1, wherein a difference in thickness between the plating formed on the lateral faces of the second portion and the plating formed on the lateral faces of the first portion is in a range from 1 μm to 2 μm.

17. The method of manufacturing a light emitting device according to claim 2, wherein a difference in thickness between the plating formed on the lateral faces of the second portion and the plating formed on the lateral faces of the first portion is in a range from 1 μm to 2 μm.
